(19) United States
(12) Patent Application Publication
(10) Pub. No.: US 2023/0395465 A1
(43) Pub. Date: Dec. 7, 2023

(54) SEMICONDUCTOR PACKAGE WITH SOLDERABLE SIDEWALL

(71) Applicant: PANJIT INTERNATIONAL INC., KAOHSIUNG CITY (TW)

(72) Inventors: CHUNG-HSIUNG HO, Kaohsiung City (TW); WEI-MING HUNG, Kaohsiung City (TW); CHI-HSUEH LI, Tainan City (TW); CHIEN-CHUN WANG, Tainan City (TW); JENG-SIAN WU, Taoyuan City (TW)

(21) Appl. No.: 17/830,592

(22) Filed: Jun. 2, 2022

(51) Int. Cl. H01L 23/48; H01L 23/31; H01L 21/768

(52) U.S. Cl. CPC H01L 23/481; H01L 23/3121; H01L 21/76879; H01L 21/76816; H01L 2224/08245; H01L 24/16

(57) ABSTRACT

A semiconductor package with improved solderability at sidewall includes a chip, a molding compound encapsulating the chip, and multiple leads distributed at sidewalls of the semiconductor package. The leads are formed as a conductive layer that is electrically connected to bonding pads of the chip. Each of the leads has a stepped surface exposed from the molding compound, wherein the stepped surface is shaped by two sequentially overlapped photoresist layers. The stepped surface of each lead allows to accommodate more solder to enhance the reliability of a solder joint between the semiconductor and a printed circuit board. Therefore, the solder joints of the semiconductor package are easily inspected by automatic optical inspection (AOI) equipment.

### BACKGROUND OF THE INVENTION

### 1. Field of the Invention

The present invention relates to a semiconductor package and a method for manufacturing the same, particularly to a semiconductor package having improved solderability on the sidewall of the package.

### 2. Description of the Related Art

With reference to FIGS. 7A to 7G, a conventional packaging process for forming a semiconductor package is illustrated. In FIG. 7A, a lead frame 100 comprises a plurality of leads 102 interconnected by supporting bars 102. The lead frame 100 further includes multiple plating ribs 103 for electroplating process.

As shown in FIGS. 7B and 7C, chips 200 are bonded on the lead frame 100 and electrically connected to respective leads 102 through metal wires 201 by a wire bonding process. In FIG. 7C, each chip 200 is electrically connected to six respective leads 102 through the metal wires 201.

After the wire bonding process, a molding process is performed on the lead frame 100 and the chip 200 to encapsulate the chip 200 by a molding compound 300. As shown in FIG. 7E, an initial sawing process is applied to cut the lead frame 100 along first paths (shown in broken lines) in an X direction, i.e. cutting along the supporting bars 101. After the initial sawing process, the cross section of each lead 102 is exposed.

After the initial sawing process along the X direction, an electroplating process is performed on the lead frame 100. With reference to FIG. 7F, during the electroplating process, electricity can be applied on the plating ribs 103, so that an electroplating layer such as the tin layer can be formed on the exposed cross section of each lead 102. After the electroplating process, a final sawing process is performed to cut the lead frame 100 along second paths (shown in broken lines) on FIG. 7F in a Y direction. The singular semiconductor package is shown in FIG. 7G, wherein the cutting sections of the supporting bars 101 are directly exposed without any electroplating material, resulting in the problem of copper exposure 400 on the cutting sections of the supporting bars 101.

As discussed above, the cross section of each lead 102 is electroplated to form the tin layer. However, the conventional manufacturing method performing the sawing process twice, i.e. the initial sawing along the X direction and the final sawing along the Y direction, is relatively complex. Further, the problem of copper exposure is unavoidable after the final sawing.

### SUMMARY OF THE INVENTION

An objective of the present disclosure is to provide a semiconductor package.

According to one embodiment, the semiconductor package comprises:
a conductive substrate having a first surface and a second surface;
a chip bonded on the conductive substrate and comprising
   a top surface on which a top bonding pad is formed; and
   a bottom surface on which a bottom bonding pad is formed and electrically contacts the first surface of the conductive substrate;
a molding compound encapsulating the chip and forming a first via and a second via in the molding compound;
a conductive layer filling in the first via and the second via as leads of the semiconductor package, wherein the conductive layer in the first via is electrically connected to the bottom bonding pad on the bottom surface of the chip, and the conductive layer in the second via is electrically connected to the top bonding pad on the top surface of the chip;
a first solder mask layer covering the second surface of the conductive substrate;
a second solder layer covering a part of the molding compound and distributed among the leads of the semiconductor package
wherein each lead has:
   a first surface exposed from a sidewall of the semiconductor package where the lead is formed; and
   a second surface exposed from the second solder mask layer;
   wherein, the first surface and the second surface of each lead are perpendicularly adjacent to each other and coated with an anti-oxidation layer.

According to another embodiment, a semiconductor package with improved solderability on the sidewall comprises:
a conductive substrate having a first surface and a second surface;
a chip bonded on the conductive substrate and comprising
   a top surface on which a top bonding pad is formed; and
   a bottom surface on which a bottom bonding pad is formed and electrically contacts the first surface of the conductive substrate;
a molding compound encapsulating the chip and forming a first via and a second via in the molding compound;
a conductive layer filling in the first via and the second via as leads of the semiconductor package, wherein the conductive layer in the first via is electrically connected to the bottom bonding pad on the bottom surface of the chip, and the conductive layer in the second via is electrically connected to the top bonding pad on the top surface of the chip;
a first solder mask layer covering the second surface of the substrate; and
a second solder layer covering a part of the molding compound and distributed among the leads of the semiconductor package;
wherein each lead has a stepped surface exposed from the molding compound, the stepped surface is composed of a first curved surface, a second curved surface and a vertical surface sequentially adjoined.

The semiconductor package and its manufacturing method do not need a conventional lead frame and do not perform sawing processes twice. Therefore, the problem of copper exposure resulting from dual sawing can be avoided.

Other objectives, advantages and novel features of the invention will become more apparent from the following detailed description when taken in conjunction with the accompanying drawings.

### BRIEF DESCRIPTION OF THE DRAWINGS

FIGS. 1A to 1K are cross-sectional views showing a first embodiment method for manufacturing a semiconductor package of the present disclosure;

FIG. 2 shows the semiconductor package shown in FIG. 1K being connected on a PCB;

FIG. 3A shows a perspective view of a semiconductor package manufactured by the first embodiment method;

FIG. 3B shows a perspective view of another semiconductor package manufactured by the first embodiment method;

FIG. 3C shows a perspective view of yet another semiconductor package manufactured by the first embodiment method;

FIG. 4A to 4N are cross-sectional views showing a second embodiment method for manufacturing a semiconductor package of the present disclosure;

FIG. 5 shows the semiconductor package shown in FIG. 4M being connected on a PCB;

FIG. 6 shows a perspective view of the semiconductor package manufactured by the second embodiment method; and

FIGS. 7A to 7G are cross-sectional views showing a conventional method of manufacturing a semiconductor package.

### DETAILED DESCRIPTION OF THE INVENTION

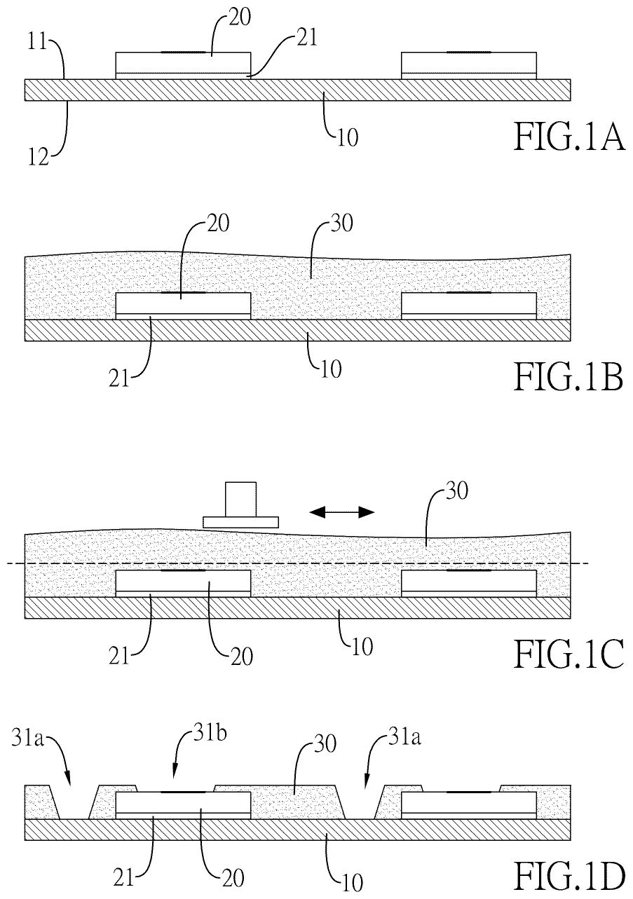

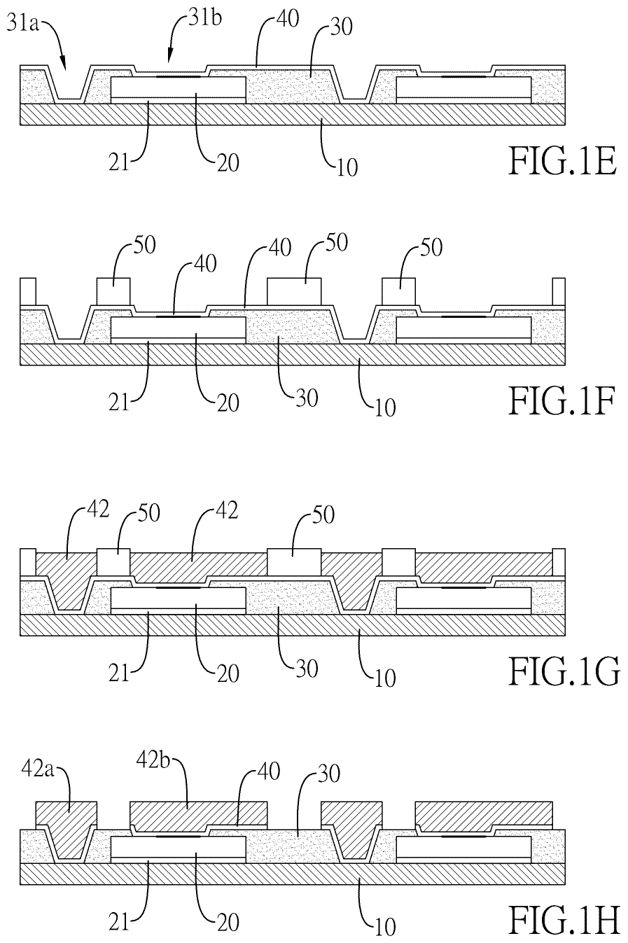

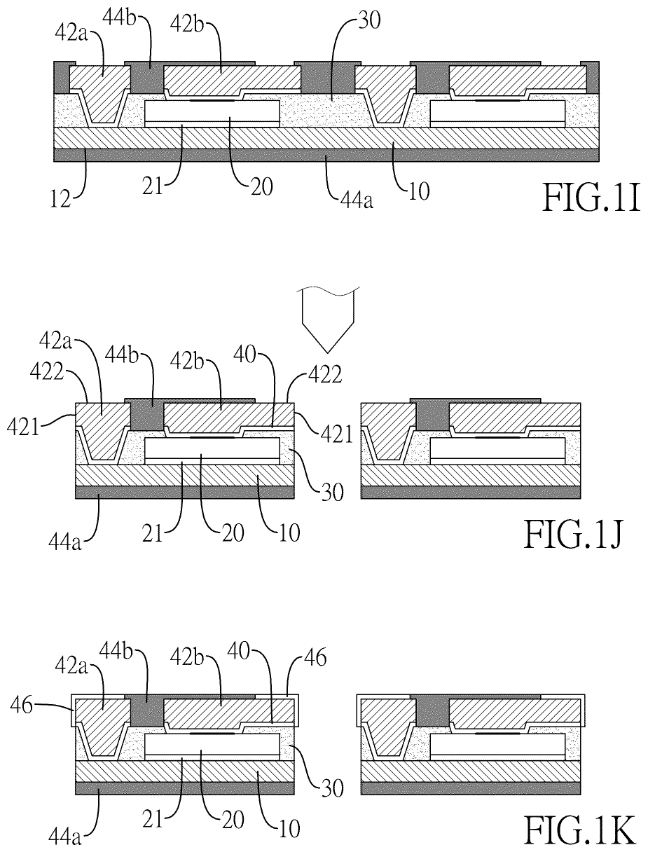

With reference to FIGS. 1A to 1K, a manufacturing process for manufacturing a semiconductor package according to a first embodiment of the present disclosure is shown. In FIG. 1A, multiple chips 20 are bonded on a first surface 11 of a conductive substrate 10 such as a copper substrate through the die bonding process. Each chip 20 has a bottom bonding pad 21 formed on a back surface of the chip 20 to be attached on the first surface 11 of the conductive substrate 10. The bonding pad 21 is a back-side metal pad formed by, for example, sputtering process for electrically connecting the chip 20 to a circuit board. In one or more embodiments, each chip 20 further includes a top bonding pad formed on a top surface of the chip 20.

With reference to FIG. 1B, a molding compound 30 such as polypropylene (PP) molding compound, epoxy molding compound (EMC) or other dielectric compound is applied on the conductive substrate 30 to encapsulate the chips 20. After forming the molding compound, a flattening process is optionally used to grind and clean a top surface of the molding compound 30 to obtain a flat surface.

With reference to FIG. 1D, multiple first vias 31a and second vias 31b are formed in the molding compound 30. The number and positions of the first vias 31a and the second vias 31b are determined based on package specification. For example, all the first vias 31a may be distributed at the same side of the chip 20, or distributed at two opposite sides of the chip 20, or distributed around the periphery of the chip 20. Each first via 31a is formed through the molding compound 30 to expose the conductive substrate 10. Each of the second vias 31b extends from the top surface of the molding compound 30 to the top surface of the chip 20. The first vias 31a and the second vias 31b may be formed by laser drilling, ultrasonic drilling, micro electrical discharge machining, micro powder blasting, inductively coupled plasma reactive ion etching (ICP-RIE), etc. The terms “first” and “second” describing the vias are for indicating the vias formed at different positions, thereby distinguishing the different types of vias.

With reference to FIG. 1E, a plating layer 40 is formed on an inner wall of each first via 31a and each second via 31b as well as on the top surface of the molding compound 30. The plating layer 40 can be formed by electro-less plating, sputtering, etc. Preferably, the plating layer 40 is made of Ti/Cu.

With reference to FIGS. 1F and 1G, a photoresist layer 50 is applied on the plating layer 40. After exposing and developing the photoresist layer 50, the first vias 31a and the second vias 31b are exposed from the photoresist layer 50 to show the plating layer 40. A conductive layer 42, preferably a copper layer, further fills each first via 31a and each second via 31b.

With reference to FIG. 1H, after filling the first vias 31a and the second vias 31b with the conductive layer 42, the photoresist layer 50 and the plating layer 40 below the photoresist layer 50 are removed such that the conductive layer 42 forms a plurality of leads 42a, 42b. In one embodiment, the plurality of leads 42a, 42b are separated from each other. In other embodiments, the conductive layer 42 in some first vias 31a and/or some second vias 31b are electrically connected together to form a common lead (not shown).

With reference to FIG. 1I, a first solder mask layer 44a is formed on a second surface 12 of the conductive substrate 10 and a second solder mask layer 44b is formed on the molding compound 30 and portions of the leads 42a, 42b to avoid moisture and oxidation. Since the second solder mask layer 44b is provided among the leads 42a, 42b, the second solder mask layer 44b can be used as a solder resist layer to prevent the adjacent leads 42a, 42b from short circuiting.

With reference to FIGS. 1J to 1K, a sawing process is performed along scribe lines to singulate each chip 20 from other chips to form individual semiconductor packages. An anti-oxidation layer 46 is further coated on exposed surfaces of each lead 42a, 42b. The anti-oxidation layer 46 may be an organic solderability preservative (OSP), an electroless tin layer, an electroless nickel immersion gold (ENIG) layer, a hot air solder leveling (HASL) layer, etc. For each lead 42a, 42b, the anti-oxidation layer 46 covers both a first surface 421 resulting from sawing process and a second surface 422 uncovered by the second solder mask layer 44b. As seen from the cross-sectional view of semiconductor package, the first surface 421 is perpendicularly adjacent to the second surface 422 in an L-shape, while the first surface 421 is coplanar with the sidewall of the molding layer 30.

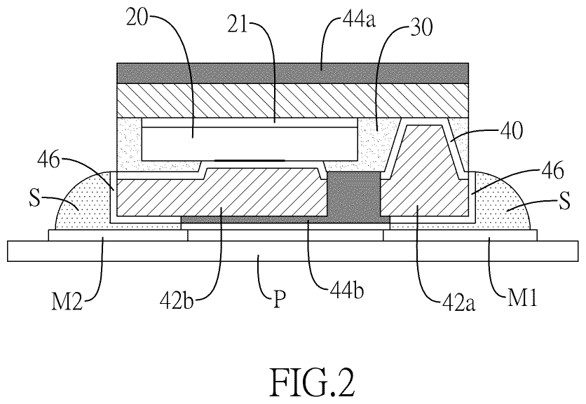

With reference to FIG. 2, the semiconductor package shown in FIG. 1K is turned over to be assembled on a circuit board P. The bottom bonding pad 21 of the chip 20 is electrically connected to the lead 42a through the conductive substrate 10. Bottom surfaces of the leads 42a, 42b are on the same plane to be soldered on the circuit board P. The leads 42a, 42b are respectively and electrically jointed to metal pads M1, M2 of the circuit board P through solder S, wherein the side surface and bottom surface of each lead 42a, 42b are solderable by the solder S to increase solder jointing area and ensure the reliability of the solder joints. Furthermore, automatic optical inspection (AOI) equipment is able to detect formation of solder fillets on the circuit board P to determine soldering quality.

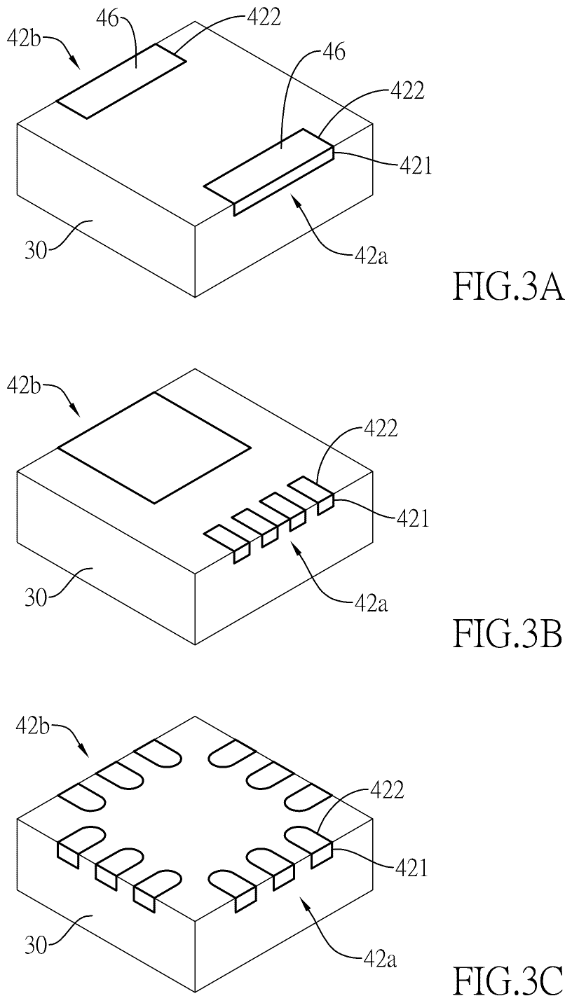

FIG. 3A shows a perspective view of an embodiment of the semiconductor package manufactured by the method described above. The semiconductor package has two leads 42a, 42b formed on opposite sides of the semiconductor package. Each lead 42a, 42b has a first surface 421 exposed from a sidewall of the semiconductor package, and a second surface 422 exposed from a bottom surface of the semiconductor package, wherein an anti-oxidation layer 46 is plated on the first surface 421 and the second surface 422.

FIG. 3B shows a perspective view of another embodiment of the semiconductor package manufactured by the method described above. The semiconductor package forms one lead 42b on one side of the semiconductor package and multiple leads 42a on an opposite side of the semiconductor package. FIG. 3C shows a perspective view of yet another embodiment of the semiconductor package manufactured by the foregoing method. The semiconductor package forms a plurality of leads 42a, 42b on each side, such as a quad flat no-lead package (QFN) semiconductor package.

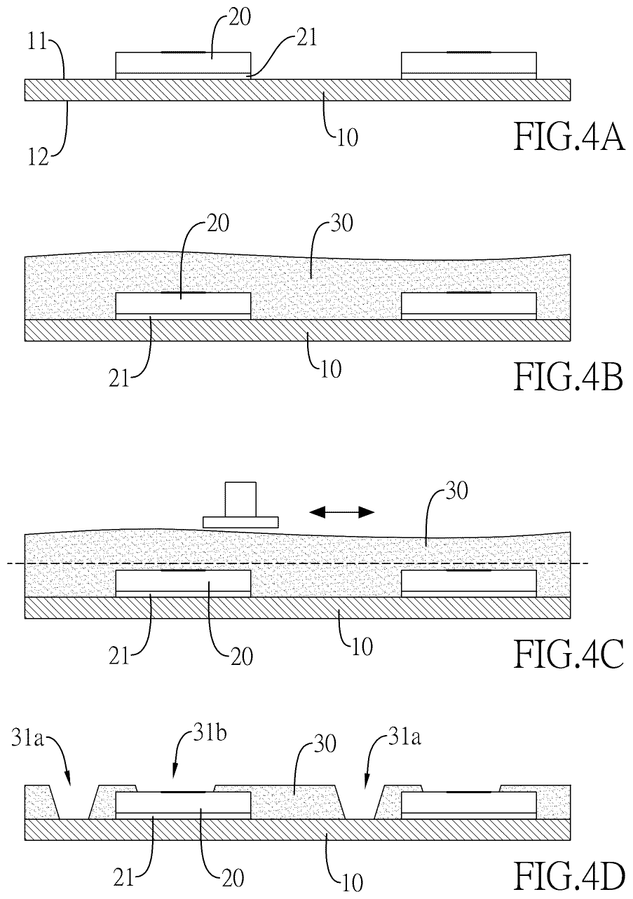

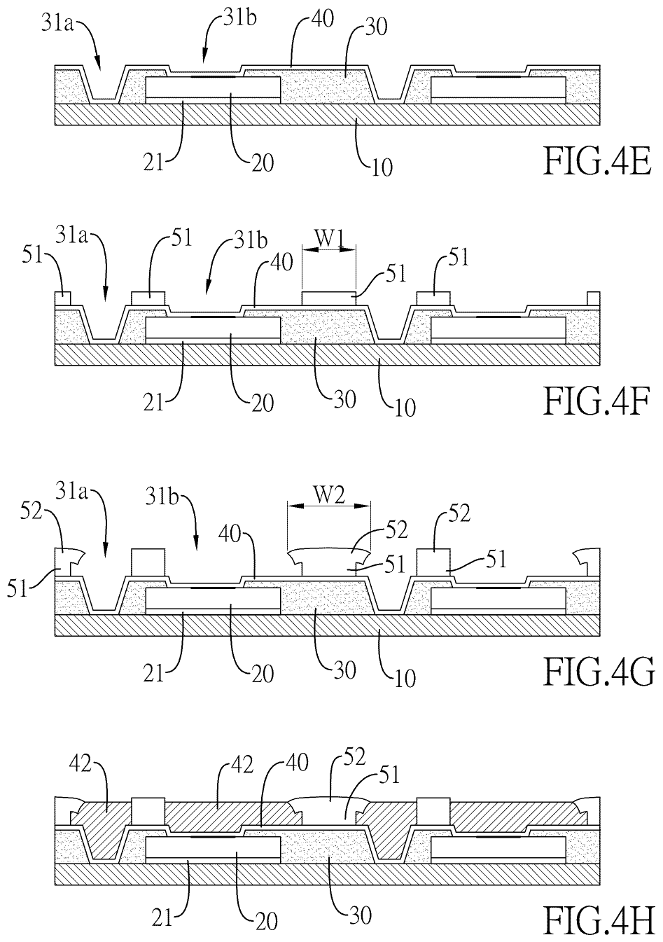

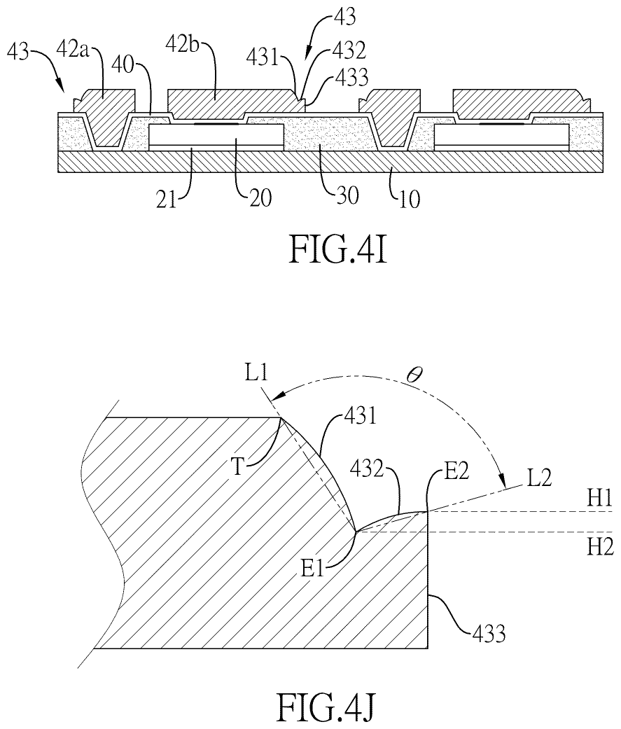

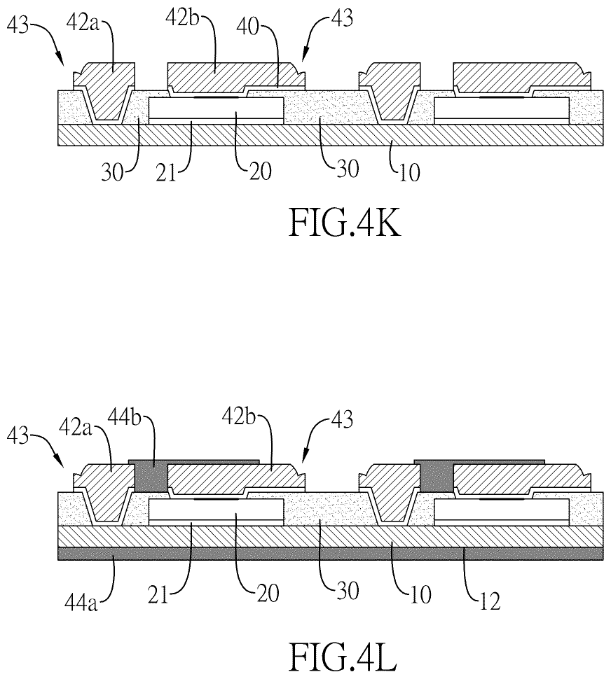

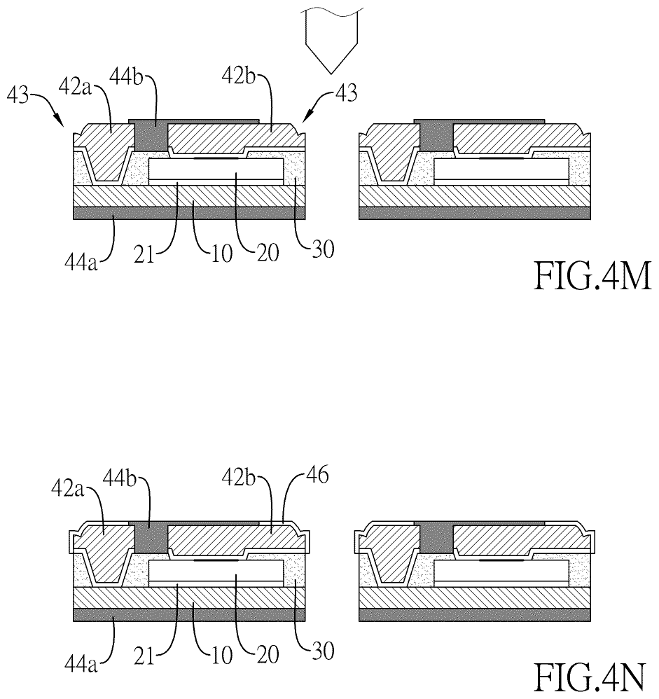

With reference to FIGS. 4A to 4M, another method embodiment for manufacturing the semiconductor package is shown. In the second embodiment, the same reference numbers and symbols as those in the first embodiment are used. Since the manufacturing processes shown in FIGS. 4A to 4E are the same as FIGS. 1A to 1E, the description thereof are omitted.

With reference to FIG. 4F, a first photoresist layer 51 is coated and patterned on the plating layer 40 as a mask, the photoresist layer 51 forms a plurality of through windows respectively corresponding to the first vias 31a and second vias 31b to show the plating layer 40.

With reference to FIG. 4G, a second photoresist layer 52 is further applied to overlap on the surface of the first photoresist layer 51 to form an accumulated photoresist layer. Preferably, the accumulated photoresist layer has a thickness the same as the thickness of the photoresist layer 50 in the foregoing first embodiment. After the second photoresist layer 52 is patterned and developed, a plurality of through windows corresponding to the first vias 31a and the second vias 31b are formed so that the plating layer 40 can be exposed in the through windows of the second photoresist layer 52.

Comparing FIGS. 4F and 4G, a photomask for defining the pattern of the second photoresist layer 52 is determined in such a way that for the photoresist layer 52 expected to define the leads of the semiconductor package, the photoresist layer 52 should have a width W2 greater than the width W1 of the first photoresist layer 51 that is under the photoresist layer 52, i.e. W2>W1. When the second photoresist layer 52 is made of negative photoresist, the portions of the second photoresist layer 52 exposed to light through light-exposure openings are insoluble to the photoresist developer. By enlarging the size of the light-exposure openings of the photomask to be greater than the respective first photoresist layer 51, the developed second photoresist layer 52 accordingly has a coverage area larger than the respective first photoresist layer 51 and the edge of the second photoresist layer 52 slightly droops due to gravity. A composite photoresist layer formed by the first photoresist layer 51 and the second photoresist layer 52 accordingly has a wide top edge and a narrow bottom portion.

With reference to FIG. 4H, a conductive layer 42 is formed in the through windows uncovered by the first photoresist layer 51 and the second photoresist layer 52 to fill the first vias 31a and the second vias 31b. Preferably, the conductive layer 42 is a copper layer.

With reference to FIG. 4I, after forming the conductive layer 42, the first photoresist layer 51 as well as the second photoresist layer 52 are removed such that the conductive layer 42 forms a plurality of leads 42a, 42b. Because the composite photoresist layer is formed in a shape having a wide top edge and a narrow bottom portion, the composite photoresist layer can be easily removed by etchant without residue. In one embodiment, the conductive layer 42 in each first via 31a or in each second via 31b forms an individual lead. In other embodiments, the conductive layer 42 in different first vias 31a and/or second vias 31b are commonly connected together to form a lead (not shown).

When the composite photoresist layer is removed, a stepped surface 43 is formed on a sidewall of the lead 42a, 42b. The stepped surface 43 is composed of a first curved surface 431, a second curved surface 432 and a vertical surface 433 which are sequentially adjoined edge by edge. The first curved surface 431 and the second curved surface 432 are convex surfaces. The vertical surface 433 is a flat surface being coplanar with the sidewall of the semiconductor package.

With reference to FIG. 4J showing an enlarged view of the steeped surface 43, the first curved surface 431 is connected to the second curved surface 432 along a first adjoining edge E1. The second curved surface 432 is connected to the vertical surface along a second adjoining edge E2. It is noted that the first adjoining edge E1 and the second adjoining edge E2 are on different horizontal planes H1, H2 respectively.

An included angle θ between the first curved surface and the second curved surface is greater than 90 degrees. The included angel θ is defined by a first virtual line L1 and a second virtual line L2. The first virtual line L1 passes through a top edge T of the first curved surface 431 and the first adjoining edge E1. The second virtual line L2 passes through the first adjoining edge E1 and the second adjoining edge E2.

With reference to FIG. 4K, the plating layer 40, previously covered by the composite photoresist layer, is removed to expose the molding compound 30.

With reference to FIG. 4L, a first solder mask layer 44a is formed on a second surface 12 of the conductive substrate 10 and a second solder mask layer 44b is formed on the molding compound 30 and covers portions of the leads 42a, 42b to avoid moisture and oxidation. The second solder mask layer 44b provided among the leads 42a, 42b also functions as an isolation layer to prevent the adjacent leads 42a, 42b from short circuiting.

With reference to FIG. 4M, a sawing process is performed along scribe lanes to singulate each chip 20 from other chips to form individual semiconductor packages.

With reference to FIG. 4N, after the sawing process, an anti-oxidation layer 46 is further provided on the exposed surface of each lead 42a, 42b. The anti-oxidation layer 46 may be an organic solderability preservative (OSP), an electroless tin layer, an electroless nickel immersion gold (ENIG) layer, a hot air solder leveling (HASL) layer, etc. The anti-oxidation layer 46 covers the stepped surface 43 and another surface that is uncovered by the solder mask layer 44 of each lead 42a, 42b.

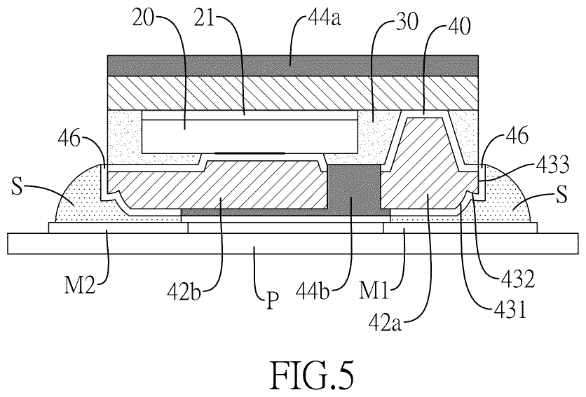

With reference to FIG. 5, the semiconductor package differs from the first embodiment shown in FIG. 2 in that each of the leads 42a, 42b has a stepped surface 43. When the semiconductor package is mounted to the circuit board P, the stepped surface 43 can accommodate more solder S to increase solder jointing area and enhance the reliability of the solder joints.

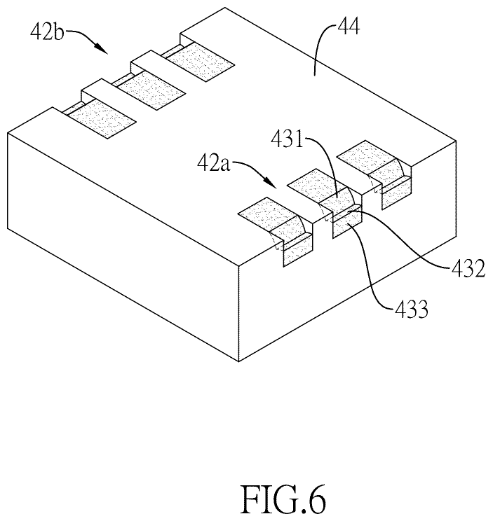

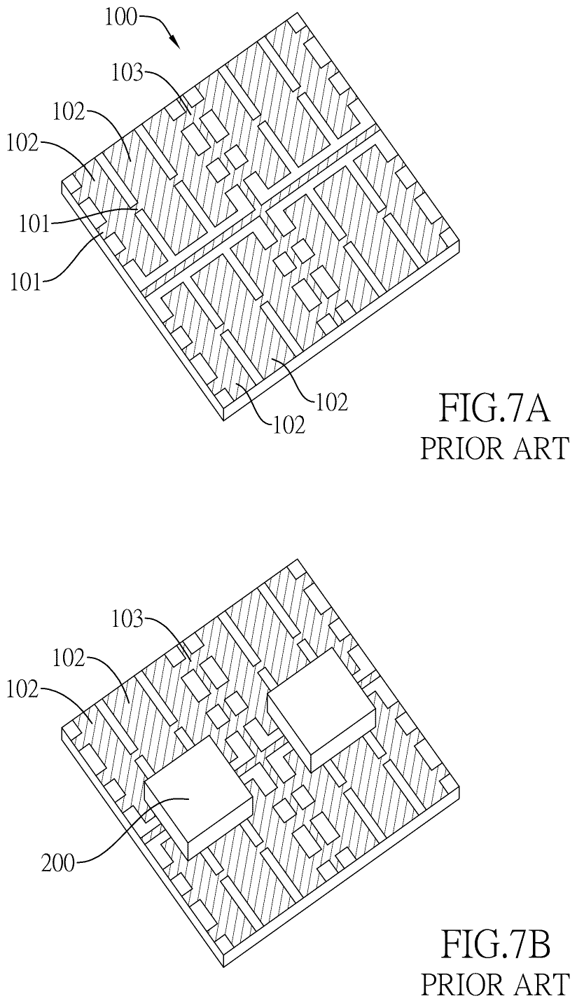

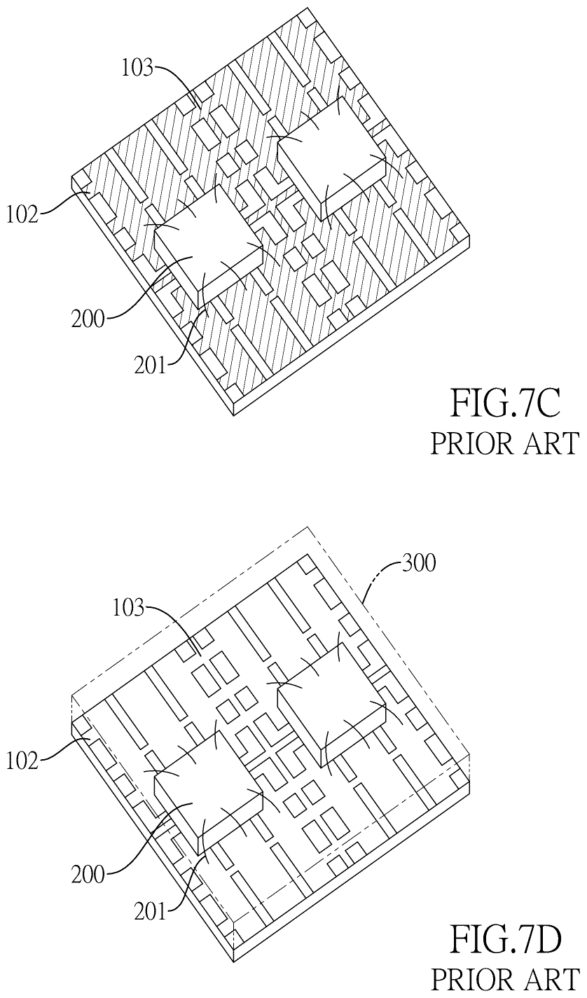

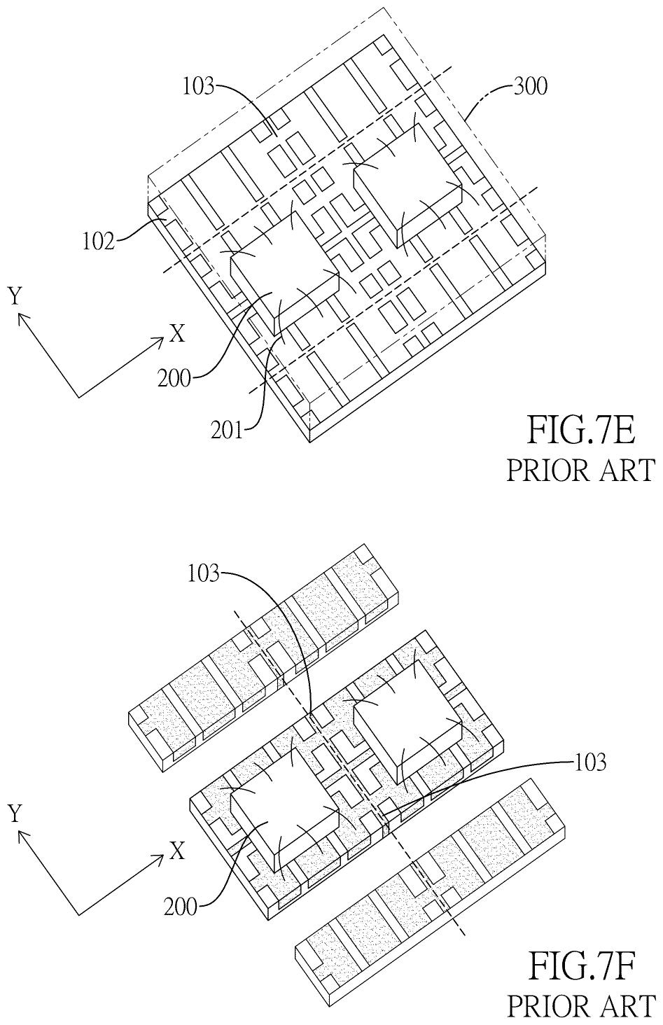

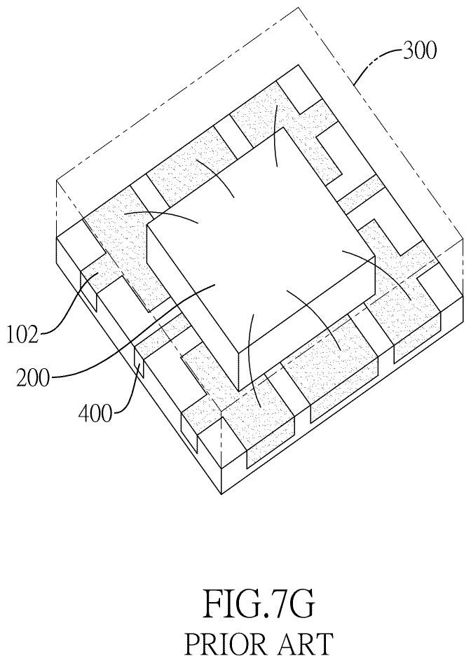

With reference to FIG. 6, the semiconductor package manufactured by the second embodiment method described above has leads 42a, 42b formed on opposite sides of the semiconductor package. Each lead 42a, 42b has a stepped surface 43. It is noted that in other embodiment, the semiconductor package shown in FIGS. 3A to 3C may have the leads 42a, 42b with the stepped surface formed by the foregoing second method embodiment.

In short, the semiconductor package and manufacturing method thereof in accordance with the present disclosure may have the following features:

1. According to at least one embodiment of the present disclosure, each lead distributed at the sidewall of the semiconductor package can be fully covered with solder, thereby increasing contact area between the lead and the solder to ensure soldering quality.

2. According to at least one embodiment of the present disclosure, the composite photoresist layer is used to define the appearance of the semiconductor package leads with stepped surfaces to accommodate more solder for increasing solder jointing area and ensuring the reliability of the solder joints.

3. According to the present disclosure, the manufacturing method only performs the sawing process once to avoid the problem of copper exposure, rather than performing the initial sawing step, electroplating step and final sawing step in sequence.

4. The manufacturing method does not need to use the lead frame and perform wire bonding process.

5. Conductive material such as copper fills the first vias and the second vias to form semiconductor package leads in contact with the chip. A larger contact area between the leads and the chips is able to improve heat dissipation.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A semiconductor package with improved solderability on a sidewall comprising:
a conductive substrate having a first surface and a second surface;
a chip bonded on the conductive substrate and comprising
a top surface on which a top bonding pad is formed; and
a bottom surface on which a bottom bonding pad is formed and electrically contacts the first surface of the conductive substrate;
a molding compound encapsulating the chip and forming a first via and a second via in the molding compound;
a conductive layer filling in the first via and the second via as leads of the semiconductor package, wherein the conductive layer in the first via is electrically connected to the bottom bonding pad on the bottom surface of the chip, and the conductive layer in the second via is electrically connected to the top bonding pad on the top surface of the chip;
a first solder mask layer covering the second surface of the conductive substrate; and
a second solder layer covering a part of the molding compound and distributed among the leads of the semiconductor package;
wherein each lead has:
a first surface exposed from a sidewall of the semiconductor package where the lead is formed; and
a second surface exposed from the second solder mask layer; wherein the first surface and the second surface of each lead are perpendicularly adjacent to each other and coated with an anti-oxidation layer.

2. The semiconductor package as claimed in claim 1, wherein the first surface of each lead is coplanar with the sidewall of the molding compound.

3. The semiconductor package as claimed in claim 1, wherein the first surface and the second surface of each lead are flat surfaces.

4. The semiconductor package as claimed in claim 1, wherein a plating layer is formed on an inner wall of each first via and each second via and electrically contacts the conductive layer.

5. The semiconductor package as claimed in claim 4, wherein the first via extends to the conductive substrate, and the second hole extends to the top bonding pad of the chip.

6. The semiconductor package as claimed in claim 1, wherein
the second surfaces of all the leads of the semiconductor package are exposed on the same plane of the semiconductor package; and
the first surfaces of all the leads of the semiconductor package are exposed on opposite sidewalls of the semiconductor package.

7. The semiconductor package as claimed in claim 1, wherein
the bottom bonding pad of the chip is electrically connected to the conductive layer in the first via through the conductive substrate, without using bonding wires;
the top bonding pad of the chip is electrically connected to the conductive layer in the second via without using bonding wires.

8. A semiconductor package with improved solderability on a sidewall comprising:
a conductive substrate having a first surface and a second surface;
a chip bonded on the conductive substrate and comprising
a top surface on which a top bonding pad is formed; and
a bottom surface on which a bottom bonding pad is formed and electrically contacts the first surface of the conductive substrate;
a molding compound encapsulating the chip and forming a first via and a second via in the molding compound;
a conductive layer filling in the first via and the second via as leads of the semiconductor package, wherein the conductive layer in the first via is electrically connected to the bottom bonding pad on the bottom surface of the chip, and the conductive layer in the second via is electrically connected to the top bonding pad on the top surface of the chip;
a first solder mask layer covering the second surface of the substrate; and
a second solder layer covering a part of the molding compound and distributed among the leads of the semiconductor package;
wherein each lead has a stepped surface exposed from the molding compound, the stepped surface is composed of a first curved surface, a second curved surface and a vertical surface sequentially adjoined.

9. The semiconductor package as claimed in claim 8, wherein the first curved surface and the second curved surface are convex surfaces, and the vertical surface is a flat surface being coplanar with the sidewall of the semiconductor package.

10. The semiconductor package as claimed in claim 8, wherein
the first curved surface is connected to the second curved surface along a first adjoining edge;
the second curved surface is connected to the vertical surface along a first a second adjoining edge;
the first adjoining edge and the second adjoining edge are on different horizontal planes respectively.

11. The semiconductor package as claimed in claim 10, wherein
an included angle between the first curved surface and the second curved surface is greater than 90 degrees;
the included angel is defined by a first virtual line and a second virtual line, where the first virtual line passes through a top edge of the first curved surface and the first adjoining edge, while the second virtual line passes through the first adjoining edge and the second adjoining edge.

12. The semiconductor package as claimed in claim 8, wherein a plating layer is formed on an inner wall of each first via and each second via and electrically contacts the conductive layer.

13. The semiconductor package as claimed in claim 8, wherein the first via extends to the conductive substrate, and the second hole extends to the top bonding pad of the chip.

14. The semiconductor package as claimed in claim 8, wherein
the bottom bonding pad of the chip is electrically connected to the conductive layer in the first via through the conductive substrate, without using bonding wires;
the top bonding pad of the chip is electrically connected to the conductive layer in the second via without using bonding wires.
